(19) United States
(12) Patent Application Publication
(10) Pub. No.: US 2022/0319582 A1
(43) Pub. Date: Oct. 6, 2022

(54) MEMORY MANAGEMENT APPARATUS, MEMORY MANAGEMENT METHOD, AND COMPUTER-READABLE RECORDING MEDIUM STORING MEMORY MANAGEMENT PROGRAM

(71) Applicant: FUJITSU LIMITED, Kawasaki-shi (JP)

(72) Inventors: Satoshi Nakagawa, Fuchu (JP); Yasuhiro Kitamura, Kawasaki (JP)

(73) Assignee: FUJITSU LIMITED, Kawasaki-shi (JP)

(21) Appl. No.: 17/582,039

(22) Filed: Jan. 24, 2022

(30) Foreign Application Priority Data
Apr. 5, 2021 (JP) 2021-064148

(51) Int. Cl. G11C 11/406; G11C 11/4076; G11C 11/4096

(52) U.S. Cl. CPC G11C 11/40615; G11C 11/40626; G11C 11/4076; G11C 11/4096

(57) ABSTRACT

A memory management apparatus includes a memory, and a processor coupled to the memory and configured to receive a notification of issuance of an activation instruction to each bank included in a predetermined group among a plurality of banks included in the memory, count a number of the received notifications, cause the memory to be refreshed in a case where a count value of the counting reaches a refresh threshold, and reduce the count value by a value of the refresh threshold in a case where the memory is refreshed.

### CROSS-REFERENCE TO RELATED APPLICATION

This application is based upon and claims the benefit of priority of the prior Japanese Patent Application No. 2021-64148, filed on Apr. 5, 2021, the entire contents of which are incorporated herein by reference.

### FIELD

The embodiments discussed herein are related to a memory management apparatus, a memory management method, and a memory management program.

### BACKGROUND

A dynamic random access memory (DRAM), or the like, is widely used as a main memory of a computer, because it has a simple structure and a product with a large capacity may be produced at a relatively low price. The DRAM is regularly refreshed to hold information. Moreover, with a recent increase in integration of the DRAM, use of a DRAM with a function called refresh management, which performs additional refresh in addition to regular refresh, is also increasing.

Hereinafter, the refresh management in a DRAM is briefly described. The DRAM accepts an activate (ACT) command, which is an activation instruction for starting driving before reading or writing. A memory access controller (MAC) has a rolling accumulated activate (RAA) counter for each bank of the DRAM. In addition, the memory access controller increments the RAA counter of a destination bank each time the ACT command is issued to each bank. When the RAA counter becomes equal to or greater than an RAA initial management threshold (RAAIMT), the memory access controller issues a refresh management (RFM) command as additional refresh. When the RFM command is issued, the memory access controller subtracts the RAA counter by the RAAIMT.

The memory access controller subtracts the RAA counter by the RAAIMT also in a case where a refresh (REF) command for regular refresh is issued. Note that, in a case where a value of the RAA counter is smaller than the RAAIMT, the RAA counter does not become negative and becomes 0.

While the ACT command is issued to a specific bank, there are two types of RFM commands with different destinations. One is an RFM all bank (RFMab) command, which is addressed to all banks in all bank groups in the same rank. Another one is an RFM same bank (RFMsb) command, which is addressed to a bank with a specific bank address in all bank groups in the same rank. Furthermore, similarly, there are two types of REF commands, an REF all bank (REFab) command and an REF same bank (REFsb) command.

Furthermore, when the RAA counter reaches an RAA maximum management threshold (RAAMMT), the memory access controller suppresses issuance of the ACT command to the corresponding bank.

Regarding the refresh function of the DRAM, there is a technology in which a memory circuit for storing whether or not refresh has been executed is arranged for each memory bank and refresh timers are integrated into one. Furthermore, there is a technology in which issuance of a calibration command is suppressed within a predetermined period after issuance of a refresh command, and issuance of the refresh command is suppressed within a predetermined period after issuance of the calibration command.

Japanese Laid-open Patent Publication No. 2003-007054 and Japanese Laid-open Patent Publication No. 2016-012362 are disclosed as related art.

### SUMMARY

According to an aspect of the embodiments, a memory management apparatus includes a memory, and a processor coupled to the memory and configured to receive a notification of issuance of an activation instruction to each bank included in a predetermined group among a plurality of banks included in the memory, count a number of the received notifications, cause the memory to be refreshed in a case where a count value of the counting reaches a refresh threshold, and reduce the count value by a value of the refresh threshold in a case where the memory is refreshed.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a configuration diagram of an entire memory access controller;

FIG. 2 is a circuit diagram illustrating details of a refresh management control unit according to a first embodiment;

FIG. 3 is a time chart illustrating transition of a rolling accumulated activate (RAA) counter according to the first embodiment;

FIG. 4 is a time chart illustrating transition of the RAA counter in a case where a refresh management (RFM) issuance request according to the first embodiment is output;

FIG. 5 is a flowchart of refresh management according to the first embodiment;

FIG. 6 is a circuit diagram illustrating details of a refresh management control unit according to a second embodiment;

FIG. 7 is a time chart illustrating transition of an RAA counter according to the second embodiment;

FIG. 8 is a time chart illustrating transition of the RAA counter in a case where an RFM issuance request according to the second embodiment is output;

FIG. 9A is a first flowchart of refresh management according to the second embodiment;

FIG. 9B is a second flowchart of the refresh management according to the second embodiment; and

FIG. 10 is a hardware configuration diagram of an information processing device.

### DESCRIPTION OF EMBODIMENTS

In order to implement a refresh management function, rolling accumulated activate (RAA) counters of the total number of banks of a dual inline memory module (DIMM) to be controlled are arranged in a memory access controller. For example, a case will be described where the number of DIMMs connected to the memory access controller is 1, the number of ranks is 16, the number of bank groups is 8, and the number of banks in the same bank group is 4. In this case, the total number of banks is 16×8×4=512. On the other hand, the maximum value of the RAA counter is an RAA maximum management threshold (RAAMMT). For example, in the case of a double data rate (DDR) 5 synchronous dynamic random access memory (SDRAM), the maximum value of the RAAMMT is 6×80=480. In this case, 9 bits are used for each RAA counter. Thus, the total number of bits of a flip-flop (FF) arranged in the memory access controller is 9×512=4608 bits, and a physical amount of the RAA counters is large. In a recent large scale integration (LSI), an increase in power consumption has become a problem, and it is desired that the LSI be implemented in a circuit as small as possible. However, it is difficult to reduce a circuit scale in the memory access controller of such a system.

Note that, in the technology in which the memory circuit is arranged for each memory bank and the refresh timers are integrated into one, the number of refresh timers may be reduced. However, since the number of RAA counters is not reduced, it is difficult to suppress an increase in the circuit scale due to the RAA counters. Furthermore, in the technology in which the issuance of the calibration command and the issuance of the refresh command are suppressed for a predetermined period, since there is no influence on a scale of an RAA counter, it is difficult to suppress an increase in the circuit scale.

Hereinafter, embodiments of the technology for reducing a circuit scale and power consumption will be described in detail with reference to the drawings. Note that the following embodiments do not limit a memory management apparatus, a memory management method, and a memory management program disclosed in the present application.

### First Embodiment

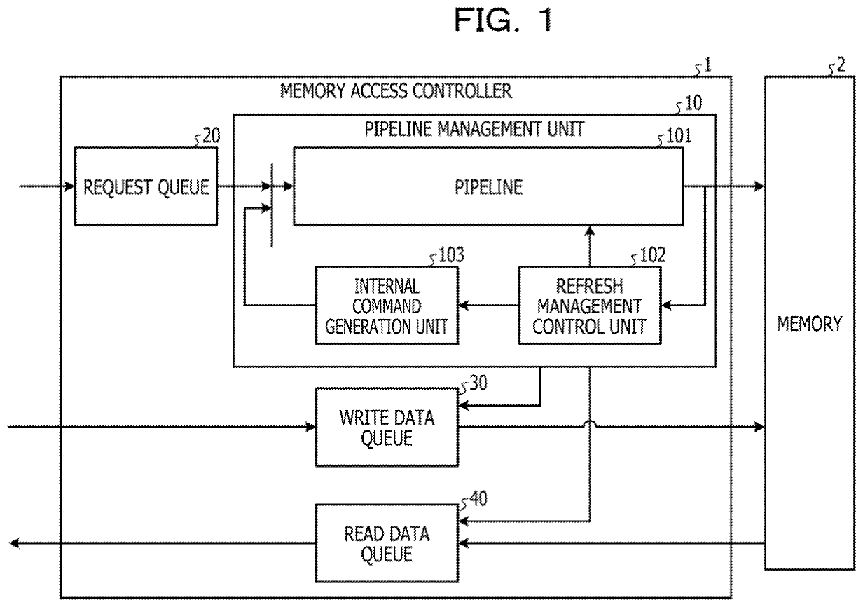

FIG. 1 is a configuration diagram of an entire memory access controller. As illustrated in FIG. 1, a memory access controller 1 according to the present embodiment includes a pipeline management unit 10, a request queue 20, a write data queue 30, and a read data queue 40.

The request queue 20 receives a memory access request. The memory access request is sent from, for example, a central processing unit (CPU) core or the like. Then, the request queue 20 accumulates the received memory access request and outputs the memory access request to the pipeline management unit 10.

The pipeline management unit 10 generates, in response to a memory access request input from the request queue 20, internal commands including commands for pipeline processing and refresh and the like. The pipeline management unit 10 includes a pipeline 101, a refresh management control unit 102, and an internal command generation unit 103.

The pipeline 101 has a plurality of series of processing steps in response to an input request. The pipeline 101 receives an input of a memory access request from the request queue 20. Furthermore, the pipeline 101 receives an input of an internal command from the internal command generation unit 103.

In response to the input memory access request or internal command, the pipeline 101 performs pipeline processing for performing processing at each processing step and transferring the processing to the next processing step. Then, the pipeline 101 outputs a command according to a processing result to a memory 2 via a physical layer of the memory 2. For example, the pipeline 101 issues an activate (ACT) command to the memory 2 for a bank specified in the memory access request. Thereafter, the pipeline 101 issues a write command or a read command to the memory 2 according to contents of the memory access request. Furthermore, the pipeline 101 issues a Pre Command to the memory 2.

The ACT command is a command that includes specification of a bank address, a bank group address, and a row address, activates (ACTIVE) a specified bank, and selects a row address. For example, the ACT command causes the bank to transition from an IDLE state to an ACTIVE state. The read command and the write command are commands that include specification of a bank address, a bank group address, and a column address, select a column address of a specified bank, and perform reading or writing. The Pre Command is a command that precharges a corresponding bank, and returns a state of the bank to IDLE, which is, initializes the bank. Furthermore, there is also a read/write with auto pre-charge (RDA/WRA) command that integrates the read command, the write command, and the Pre Command.

Furthermore, the pipeline 101 receives an input of an ACT command issuance suppression request from the refresh management control unit 102. Then, the pipeline 101 stands by for issuance of an ACT command.

The refresh management control unit 102 receives an input of an ACT command, a refresh (REF) command, a refresh management (RFM) command, and an issuance notification sent by the pipeline 101 to the memory 2. Then, the refresh management control unit 102 determines to request issuance of the RFM command and to suppress issuance of the ACT command on the basis of each acquired signal. In a case where the issuance of the RFM command is determined, the refresh management control unit 102 outputs an RFM command issuance request to the internal command generation unit 103. Furthermore, in a case where suppression of the issuance of the ACT command is determined, the refresh management control unit 102 outputs an ACT command issuance suppression request to the pipeline 101. The operation of the refresh management control unit 102 will be described in detail later.

The internal command generation unit 103 measures a predetermined time by using its own timer. Then, when the predetermined time determined in advance elapses, the internal command generation unit 103 generates an REF all bank (REFab) command or an REF same bank (REFsb) command. Whether to use the REFab command or the REFsb command is determined by, for example, a preset operation mode. Then, the internal command generation unit 103 outputs the generated REFab command or REFsb command to the pipeline 101.

Furthermore, the internal command generation unit 103 receives an RFM command issuance request from the refresh management control unit 102. Then, the internal command generation unit 103 generates an RFM all bank (RFMab) command or an RFM same bank (RFMsb) command according to the input issuance request. Thereafter, the internal command generation unit 103 outputs the generated RFMab command or RFMsb command to the pipeline 101.

The write data queue 30 receives an input of write data to the memory 2. Then, the write data queue 30 accumulates the input write data. Thereafter, the write data queue 30 receives, from the pipeline management unit 10, an input of a signal notifying that a bank of the memory 2 to be written has been activated by a memory access request. Then, the write data queue 30 outputs the write data to be written to the activated bank to the memory 2.

The read data queue 40 receives, from the pipeline management unit 10, an input of a signal notifying that a bank of the memory 2 to be read has been activated by a memory access request. Then, the read data queue 40 acquires read data read from the activated bank from the memory 2, and accumulates the acquired read data. Thereafter, the read data queue 40 sequentially outputs the read data to a destination of the read data.

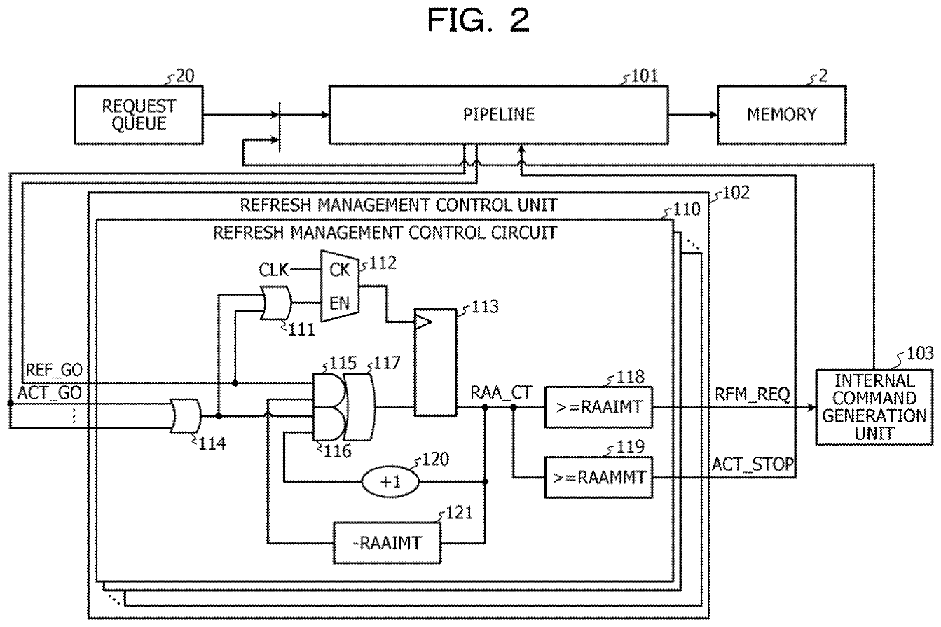

FIG. 2 is a circuit diagram illustrating details of the refresh management control unit according to the first embodiment. The refresh management control unit 102 has one refresh management control circuit 110 for each group in which a plurality of banks is grouped. The number of banks included in the one group is not particularly limited, and it is possible to make a group including all banks. The number of banks included in one group is preferably determined according to an operation of the memory 2 in consideration of a required refresh time. In the present embodiment, a case will be described where all banks in the same rank are grouped as one group and set as an object to be managed of one refresh management control circuit 110.

As illustrated in FIG. 2, the refresh management control circuit 110 includes an OR circuit 111, a clock output circuit 112, an RAA counter flip-flop (FF) 113, an OR circuit 114, an AND circuit 115, an AND circuit 116, and an OR circuit 117. Moreover, the refresh management control circuit 110 includes a comparator 118, a comparator 119, an adder 120, and a subtractor 121.

When a memory access request for the banks to be managed is input to the pipeline 101, the OR circuit 114 receives an input of an ACT_GO signal notifying that an ACT command to a bank specified by the memory access request has been issued. For example, the OR circuit 114 receives a notification of issuance of an ACT command to all banks belonging to a group managed by the refresh management control circuit 110. Then, when receiving the issuance notification of the ACT command to any one of the banks to be managed, the OR circuit 114 outputs the signal to the OR circuit 111 and the AND circuit 116.

When a memory access request for the banks to be managed is input to the pipeline 101, the OR circuit 111 receives, from the OR circuit 114, an input of an ACT_GO signal notifying that an ACT command to a bank specified by the memory access request has been issued. Then, when receiving the input of the signal from the OR circuit 114, the OR circuit 111 inputs an enable signal to the clock output circuit 112.

Furthermore, when a refresh command of either an RFM command or an REF command is issued from the pipeline 101 to the memory 2, the OR circuit 111 receives an input of an REF_GO signal notifying that the refresh command has been issued. Then, when receiving the input of the REF_GO signal, the OR circuit 111 inputs an enable signal to the clock output circuit 112.

The clock output circuit 112 receives an input of a clock (CLK) from, for example, an oscillator. In a state where an enable signal is not input, the clock output circuit 112 stands by for an output of the clock. Then, when the enable signal is input from the OR circuit 111 in response to an input of an ACT_GO signal or an REF_GO signal, the clock output circuit 112 inputs the clock to the RAA counter FF 113.

The AND circuit 115 receives, from the subtractor 121, an input of a value obtained by subtracting an RAA initial management threshold (RAAIMT) from a value of an RAA counter output from the RAA counter FF 113. Note that, in a case where the value of the RAA counter output from the RAA counter FF 113 is less than or equal to the RAAIMT, the input value is 0. Furthermore, when a refresh command of an RFM command or an REF command, which is an internal command, is input to the pipeline 101 and output from the pipeline 101, the AND circuit 115 receives an input of an REF_GO signal notifying that the refresh command has been issued. When the REF_GO signal is input, the AND circuit 115 outputs, to the OR circuit 117, the value obtained by subtracting the RAAIMT from the value of the RAA counter output from the RAA counter FF 113.

The AND circuit 116 receives, from the adder 120, an input of a value obtained by adding 1 to a value of an RAA counter output from the RAA counter FF 113. Furthermore, when a memory access request is input to the pipeline 101, the AND circuit 116 receives an input of an ACT_GO signal. When receiving the input of the ACT_GO signal, the AND circuit 116 outputs, to the OR circuit 117, the value obtained by adding 1 to the value of the RAA counter output from the RAA counter FF 113.

The OR circuit 117 receives, from the AND circuit 115, an input of a value obtained by subtracting the RAAIMT from a value of an RAA counter output from the RAA counter FF 113. Furthermore, the OR circuit 117 receives, from the AND circuit 116, an input of a value obtained by adding 1 to the value of the RAA counter output from the RAA counter FF 113. Hereinafter, the value of the RAA counter output from the RAA counter FF 113 is referred to as “RAA_CT”. When receiving the input of the value obtained by adding 1 to the RAA_CT or the input of the value obtained by subtracting the RAAIMT from the RAA_CT, the OR circuit 117 outputs the input signal to the RAA counter FF 113.

The RAA counter FF 113 receives an input of a clock from the clock output circuit 112 in a case where a memory access request is input to the pipeline 101. In that case, the RAA counter FF 113 receives, from the OR circuit 117, an input of a value obtained by adding 1 to a previously output RAA_CT. Then, the RAA counter FF 113 uses the input clock to output the value obtained by adding 1 to the previously output RAA_CT as a value of the RAA counter. For example, the new RAA_CT is the value obtained by adding 1 to the previously output RAA_CT.

The RAA counter FF 113 receives an input of a clock from the clock output circuit 112 in a case where a refresh command is input to the pipeline 101. In that case, the RAA counter FF 113 receives, from the OR circuit 117, an input of a value obtained by subtracting the RAAIMT from the previously output RAA_CT. Note that, in a case where the previously output RAA_CT is less than or equal to the RAAIMT, the value obtained by subtracting the RAAIMT from the previously output RAA_CT is 0. Then, the RAA counter FF 113 uses the input clock to output the value obtained by subtracting the RAAIMT from the previously output RAA_CT as a value of the RAA counter. For example, the new RAA_CT is the value obtained by subtracting the RAAIMT from the previously output RAA_CT. This RAA counter FF 113 corresponds to an example of a “counter”.

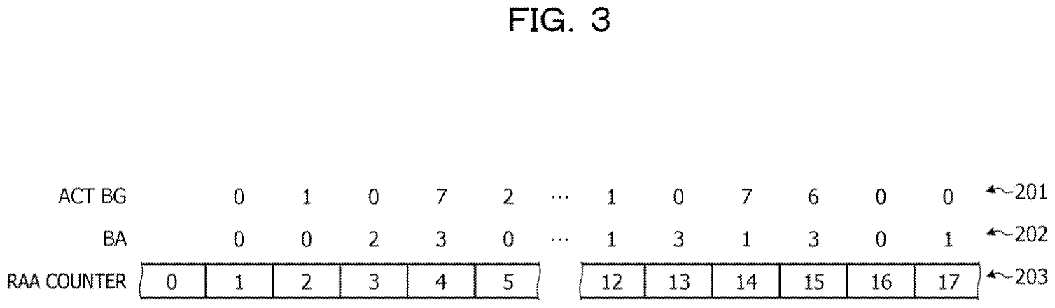

FIG. 3 is a time chart illustrating transition of the RAA counter according to the first embodiment. Lines 201 and 202 in FIG. 3 represent a bank group and a bank address to be destinations of an ACT command. In addition, a line 203 represents a value of the RAA counter. Here, since all banks in the same rank are objects to be managed, banks of bank groups of 1 to 7 are objects to be managed by one refresh management control circuit 110.

In FIG. 3, an ACT command is issued with a bank group of 0 and a bank address of 0 as destinations, whereby the RAA counter becomes 1. Next, an ACT command is issued with a bank group of 1 and a bank address of 0 as destinations, whereby the RAA counter becomes 2. Next, an ACT command is issued with a bank group of 0 and a bank address of 2 as destinations, whereby the RAA counter becomes 3. Next, an ACT command is issued with a bank group of 7 and a bank address of 3 as destinations, whereby the RAA counter becomes 4. Thereafter, the RAA counter of the refresh management control circuit 110 is incremented by one when ACT commands are issued to the banks of the bank groups 1 to 7. In this way, the value of the RAA counter in the refresh management control circuit 110 according to the present embodiment increases by one even in a case where an ACT command is issued to any one of the banks to be managed.

Returning to FIG. 2, description is continued. The comparator 118 receives an input of an RAA_CT output from the RAA counter FF 113. Then, the comparator 118 determines whether or not the RAA_CT is equal to or greater than the RAAIMT. In a case where the RAA_CT is equal to or greater than the RAAIMT, the comparator 118 outputs an RFM_REQ signal, which is an RFM command issuance request (RFM issuance request), to the internal command generation unit 103.

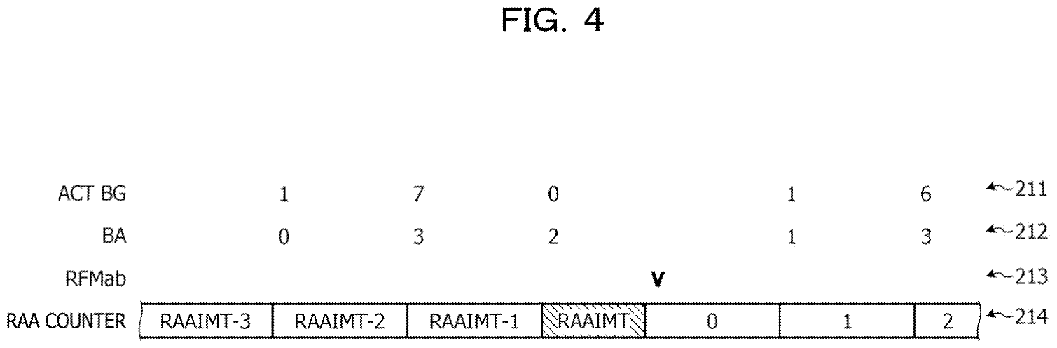

FIG. 4 is a time chart illustrating transition of the RAA counter in a case where the RFM issuance request is output. Lines 211 and 212 in FIG. 4 represent a bank group and a bank address to be destinations of an ACT command. Furthermore, a line 213 represents timing at which an RFMab is output. In addition, a line 214 represents a value of the RAA counter. Here, since all banks in the same rank are objects to be managed, banks of bank groups 1 to 7 are objects to be managed by one refresh management control circuit 110.

In FIG. 4, in a state where the value of the RAA counter is “RAAIMT-3”, an ACT command is issued with a bank group of 1 and a bank address of 0 as destinations, whereby the RAA counter is increased by one to become “RAAIMT-2”. Next, an ACT command is issued with a bank group of 7 and a bank address of 3 as destinations, whereby the RAA counter is increased by one to become “RAAIMT-1”. Next, an ACT command is issued with a bank group of 0 and a bank address of 2 as destinations, whereby the RAA counter is increased by one to become “RAAIMT”.

At this point, since the RAA counter is equal to or greater than the RAAIMT, an RFMab is output from pipeline 101 to the memory 2. In FIG. 4, a check symbol “V” represents the output of the RFMab. Then, an REF_GO signal is input to the refresh management control circuit 110, the RAAIMT is subtracted from the RAA counter, and the RAA counter becomes 0.

Thereafter, an ACT command is issued with a bank group of 1 and a bank address of 1 as destinations, whereby the RAA counter becomes 1. Thereafter, the RAA counter of the refresh management control circuit 110 is incremented by one when ACT commands are issued to the banks of the bank groups 1 to 7. In this way, in the refresh management control circuit 110 according to the present embodiment, when the total number of ACT commands issued to the banks to be managed exceeds the RAAIMT, the RFMab is sent and the RAAIMT is subtracted from the RAA counter.

For example, ACT commands of all banks included in a group to be managed are input to the refresh management control circuit 110 according to the present embodiment. Thus, the RAA counter counts all the ACT commands addressed to all the banks included in the group to be managed. Therefore, the comparator 118 may output an RFM_REQ signal even in a case where an ACT command is continuously issued to one bank having the earliest refresh timing. For example, it is possible to perform additional refresh of the memory 2 before required refresh timing, and it is possible to reliably hold information of the memory 2 and maintain performance of the memory 2.

Returning to FIG. 2, description is continued. The comparator 119 receives an input of an RAA_CT output from the RAA counter FF 113. Then, the comparator 119 determines whether or not the RAA_CT is equal to or greater than the RAAMMT. The RAAMMT is a greater value than the RAAIMT. An RFM command may not necessarily be input to the pipeline 101 immediately due to another internal command or memory access. Thus, the RAA_CT may reach the RAAMMT when the ACT command continues to be issued without the RFM command being issued.

In a case where the RAA_CT is equal to or greater than the RAAMMT, the comparator 119 outputs an ACT_STOP signal, which is an ACT issuance suppression request, to the pipeline 101. Thereafter, when an REFab or REFsb is input to the pipeline 101 by the internal command generation unit 103 that has received an input of an RFM_REQ signal and the RAAIMT is subtracted from the RAA_CT, the comparator 119 stops outputting the ACT_STOP signal. With this configuration, access to the memory 2 is restarted.

In this way, since the issuance of the ACT command is also suppressed by using the RAA counter that counts all ACT commands addressed to all banks included in a group to be managed, the suppression of the issuance of the ACT command may be executed before required timing.

The adder 120 receives an input of an RAA_CT output from the RAA counter FF 113. Then, the adder 120 outputs a value obtained by adding 1 to the RAA_CT to the AND circuit 116.

The subtractor 121 receives an input of an RAA_CT output from the RAA counter FF 113. Then, the subtractor 121 outputs a value obtained by subtracting the RAAIMT from the RAA_CT to the AND circuit 115.

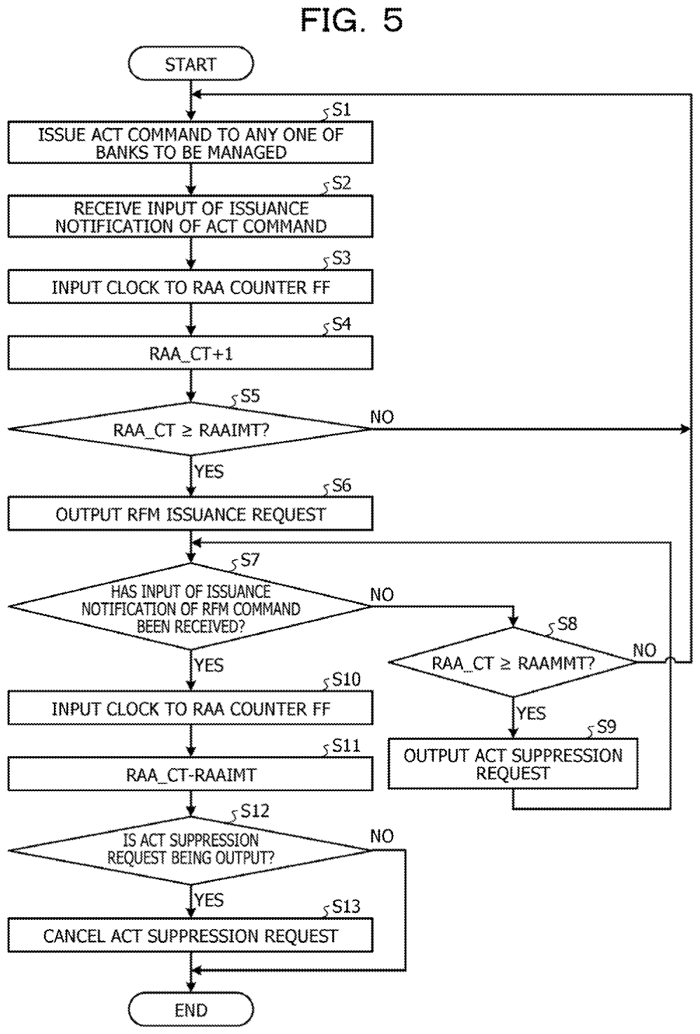

FIG. 5 is a flowchart of refresh management according to the first embodiment. Next, a flow of the refresh management according to the present embodiment will be described with reference to FIG. 5. Here, a flow of refresh by issuance of an RFM command up to RAA counter subtraction will be described.

A memory access request is input to the pipeline 101. Then, an ACT command is issued from the pipeline 101 to any one of banks to be managed of the memory 2 (operation S1).

Thereafter, the refresh management control circuit 110 receives an input of an issuance notification of the ACT command from the pipeline 101 (operation S2). An ACT_GO signal notifying issuance of the ACT command is input to the OR circuit 111 and the OR circuit 114.

When receiving the input of the ACT_GO signal, the OR circuit 114 inputs an enable signal to the clock output circuit 112. When receiving the input of the enable signal, the clock output circuit 112 inputs a clock to the RAA counter FF 113 (operation S3).

Furthermore, the OR circuit 114 outputs the input ACT_GO signal to the AND circuit 116 regardless of which bank to be managed the ACT command is addressed to. When receiving the input of the ACT_GO signal, the AND circuit 116 outputs a value obtained by adding 1 to an RAA_CT to the RAA counter FF 113 via the OR circuit 117 (operation S4).

The RAA counter FF 113 uses the clock input from the clock output circuit 112 to output the value obtained by adding 1 to the previous RAA_CT input from the AND circuit 116 as an RAA_CT. The comparator 118 determines whether the RAA_CT output from the RAA counter FF 113 is equal to or greater than the RAAIMT (operation S5). In a case where the RAA_CT is less than the RAAIMT (operation S5: No), the refresh management processing returns to the operation S1.

On the other hand, in a case where the RAA_CT is equal to or greater than the RAAIMT (operation S5: Yes), the comparator 118 outputs an RFM issuance request to the internal command generation unit 103 (operation S6).

The internal command generation unit 103 that has accepted the RFM issuance request inputs an RFM command to the pipeline 101. Thereafter, the refresh management control circuit 110 determines whether or not an input of an issuance notification of the RFM command has been received (operation S7). Here, it is determined whether or not the input of the issuance notification of the RFM command has been received depending on whether or not an REF_GO signal notifying issuance of the RFM command has been input to the OR circuit 111 and the AND circuit 115.

In a case where the input of the issuance notification of the RFM command has not been received (operation S7: No), the comparator 119 determines whether or not the RAA_CT is equal to or greater than the RAAMMT (operation S8). In a case where the RAA_CT is less than the RAAMMT (operation S8: No), the refresh management processing returns to the operation S1.

On the other hand, in a case where the RAA_CT is equal to or greater than the RAAMMT (operation S8: Yes), the comparator 119 outputs an ACT suppression request to the pipeline 101 (operation S9). Thereafter, the refresh management processing returns to the operation S7.

On the other hand, in a case where the input of the issuance notification of the RFM command has been received (operation S7: Yes), which is, in a case where the REF_GO signal is input to the OR circuit 111 and the AND circuit 115, the following processing is performed. When receiving the input of the REF_GO signal, the OR circuit 114 inputs an enable signal to the clock output circuit 112. When receiving the input of the enable signal, the clock output circuit 112 inputs a clock to the RAA counter FF 113 (operation S10).

When receiving the input of the REF_GO signal, the AND circuit 115 outputs a value obtained by subtracting the RAAIMT from the RAA_CT to the RAA counter FF 113 via the OR circuit 117 (operation S11).

Thereafter, when receiving the input of the RAA_CT having a value less than the RAAMMT, the comparator 119 determines whether or not an ACT suppression request is being output (operation S12). In a case where the ACT suppression request is not being output (operation S12: No), the comparator 119 maintains the output state in which the ACT suppression request is not being output. On the other hand, in a case where the ACT suppression request is being output (operation S12: Yes), the comparator 119 cancels the ACT suppression request (operation S13).

Thus, the processing in the flow of FIG. 5 ends, but in reality, the processing returns to the operation S1 after that, and similar refresh management processing is repeated.

By controlling the refresh management with the above configuration, for example, in a case where RAA counters in the same rank are integrated into one, the number of FFs to be deployed is 9 bits per rank, and in the case of 16 ranks, 9×16=144 bits. Therefore, a physical amount may be suppressed to 1/32 of the case where the RAA counter is provided for each bank.

As described above, the memory access controller according to the present embodiment controls issuance of an additional refresh command by using one RAA counter for a plurality of banks as objects to be managed. For example, the memory access controller performs counting at the RAA counter by using the total number of ACT commands issued to the banks to be managed, and causes an additional refresh command to be issued. With this configuration, a physical amount of the circuit that controls the refresh management may be reduced. As a result, power consumption of the memory access controller may also be reduced.

### Second Embodiment

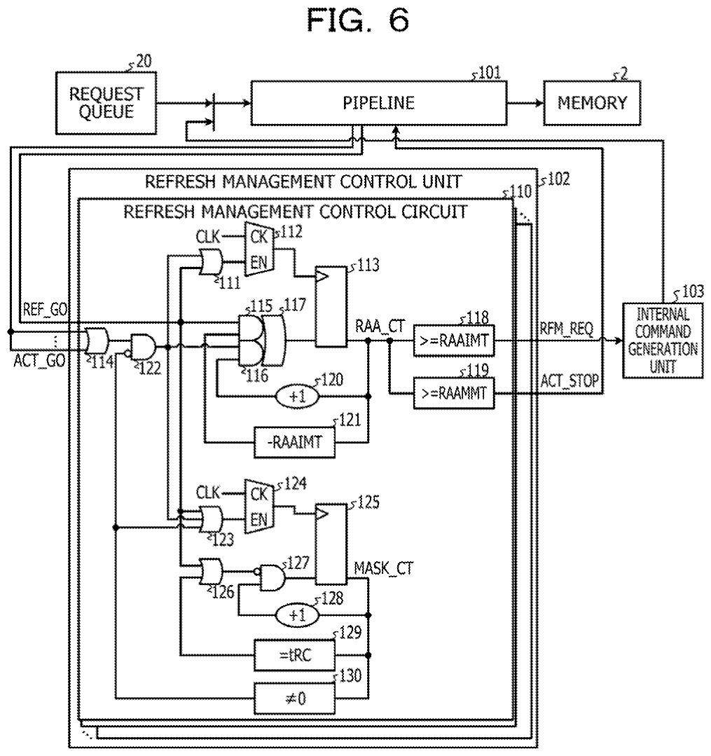

FIG. 6 is a circuit diagram illustrating details of a refresh management control unit according to a second embodiment. In the case of the configuration described in the first embodiment, since the value of the RAA counter is the total of the ACT commands issued to the banks in the same rank, the value may be greater than the number of ACT commands issued for each bank. In that case, there is also a high possibility that the RFM command will be issued excessively or that the RAA counter will exceed the RAAMMT and the ACT command may not be issued. The frequent issuance of the RFM command or the inability to issue the ACT command may hinder issuance of a read command or a write command, and may reduce processing performance of processing using the memory 2. Thus, a memory access controller 1 according to the present embodiment is different from that of the first embodiment in that, once an RAA counter is incremented, the RAA counter is not incremented for a certain period. In the following description, description of an operation of each unit similar to that of the first embodiment may be omitted.

A refresh management control circuit 110 according to the present embodiment includes an AND circuit 122, an OR circuit 123, a clock output circuit 124, a mask counter FF 125, an OR circuit 126, and an AND circuit 127 in addition to the respective units of the first embodiment. Moreover, the refresh management control circuit 110 includes an adder 128, a comparator 129, and a comparator 130.

When a memory access request is input to a pipeline 101, in a case where a bank specified by the memory access request is the bank to be managed, an OR circuit 114 receives an input of an ACT_GO signal notifying that an ACT command to the bank to be managed has been issued. Then, the OR circuit 114 outputs the signal to the AND circuit 122.

The AND circuit 122 is arranged between the OR circuit 114 and an AND circuit 116. The AND circuit 122 receives an input of signals obtained by inverting an output signal from the OR circuit 114 and an output signal from the comparator 130. Hereinafter, a signal obtained by inverting an output signal from the comparator 130 is simply referred to as an inverted signal from the comparator 130. Then, in a case where the AND circuit 122 has received the signal input from the comparator 130, the AND circuit 122 outputs a signal based on an ACT_GO signal to the AND circuit 116. As will be described later, the comparator 130 outputs a signal in a case where a value of a mask counter is other than 0, which is, a case where masking is performed. For example, in a case where masking is not performed, the AND circuit 122 receives the input of the inverted signal from the comparator 130. Therefore, in the case where masking is not performed, the AND circuit 122 outputs the signal input from the OR circuit 114 to the AND circuit 116.

When receiving an input of an REF_GO signal, an OR circuit 111 outputs the signal to a clock output circuit 112. Furthermore, in a case where masking is not performed, when receiving an input of a signal based on an ACT_GO signal from the AND circuit 122, the OR circuit 111 outputs the input signal to the clock output circuit 112.

Operations of the clock output circuit 112, an RAA counter FF 113, an AND circuit 115, an OR circuit 117, a comparator 118, a comparator 119, an adder 120, and a subtractor 121 are similar to those of the first embodiment. For example, when the signal based on the ACT_GO signal is output from the AND circuit 122, these circuits increment the RAA counter by one in a case where a value of the RAA counter is less than an RAAIMT. In addition, in a case where the value of the RAA counter is equal to or greater than the RAAIMT, these circuits request the internal command generation unit 103 to generate an RFM command. Moreover, these circuits stop issuing an ACT command to the pipeline 101 when the RAA counter becomes equal to or greater than an RAAMMT. Then, when an RFM command is issued, these circuits subtract the RAAIMT from the RAA counter.

The OR circuit 123 receives an input of an REF_GO signal. Furthermore, the OR circuit 123 receives an input of an output signal from the comparator 130. For example, in a case where masking is not performed, the OR circuit 123 receives an input of a signal based on an ACT_GO signal from the AND circuit 122. Furthermore, in a case where the mask counter FF 125 is other than 0, which is, a case where masking is performed, the OR circuit 123 receives an input of a signal output from the comparator 130. When receiving the input of any one of the signals, the OR circuit 123 outputs the signal to the clock output circuit 124. For example, in a case where masking is performed, the OR circuit 123 continues to output the signal. Furthermore, when an ACT command is issued in a case where masking is not performed, the OR circuit 123 outputs the signal. Furthermore, in a case where a refresh command is issued from the pipeline 101, the OR circuit 123 outputs the signal.

The clock output circuit 124 receives an input of a clock from an oscillator or the like. Then, when receiving an input of a signal from the OR circuit 123, the clock output circuit 124 is enabled and outputs the clock to the mask counter FF 125. For example, the clock output circuit 124 outputs the clock in a case where masking is performed, a case where masking is not performed and an ACT command is issued, and a case where a refresh command is issued.

When receiving an input of an REF_GO signal, the OR circuit 126 outputs the signal to the AND circuit 127. Furthermore, the OR circuit 126 receives an input of an output signal from the comparator 129. Here, as will be described later, the comparator 129 outputs a signal at masking cancellation timing, and does not output a signal during other periods. For example, the OR circuit 126 receives an input of a signal from the comparator 129 at the masking cancellation timing. Then, in a case where the OR circuit 126 receives the input of the REF_GO signal or the input of the signal from the comparator 129 at the masking cancellation timing, the OR circuit 126 outputs the signal to the AND circuit 127.

The AND circuit 127 receives an input of a signal obtained by inverting an output signal from the OR circuit 126. For example, the AND circuit 127 stops receiving the input of the signal from the OR circuit 126 in a case where a refresh command is issued and at masking cancellation timing. Hereinafter, a signal obtained by inverting an output signal from the OR circuit 126 is referred to as an inverted signal from the OR circuit 126. Furthermore, the AND circuit 127 receives, from the adder 128, an input of a value obtained by adding 1 to a previously output value of a mask counter. Then, in a case where the AND circuit 127 has received the input of the inverted signal from the OR circuit 126, the AND circuit 127 outputs the value obtained by adding 1 to the previously output value of the mask counter to the mask counter FF 125. For example, the AND circuit 127 stops outputting a signal to the mask counter FF 125 in a case where a refresh command is issued and at the masking cancellation timing.

The mask counter FF 125 receives an input of a clock from the clock output circuit 124. Furthermore, the mask counter FF 125 receives an input of a previously output value of a mask counter from the AND circuit 127 except when a refresh command is issued or except masking cancellation timing. Then, the mask counter FF 125 outputs the value input from the AND circuit 127 according to the clock. On the other hand, in a case where a refresh command is issued and at the masking cancellation timing, the mask counter FF 125 does not receive an input of a signal from the AND circuit 127, so the mask counter FF 125 outputs 0 as a value of the mask counter. For example, the mask counter FF 125 initializes the mask counter to 0 at this timing. Hereinafter, a value of a mask counter output from the mask counter FF 125 is represented as “MASK_CT”.

The adder 128 receives an input of a MASK_CT output from the mask counter FF 125. Then, the adder 128 outputs a value obtained by adding 1 to the input MASK_CT to the AND circuit 127.

The comparator 129 receives an input of a MASK_CT output from the mask counter FF 125. Then, the comparator 129 compares the input MASK_CT with tRC. Here, the tRC is row address select (RAS) cycle time. The tRC indicates an issuance interval of an ACT command that selects a row address. For example, after an ACT command is issued to one bank, an ACT command is not issued to the same bank during a tRC period. The minimum value of the tRC is specified by the Joint Electron Device Engineering Council (JEDEC). When the MASK_CT is not the tRC, the comparator 129 does not output a signal. Then, when the MASK_CT reaches the tRC, the comparator 129 outputs a signal. In this case, timing when the MASK_CT reaches the tRC is masking cancellation timing. This tRC corresponds to an example of a “predetermined period”.

The comparator 130 receives an input of a MASK_CT output from the mask counter FF 125. Then, the comparator 130 determines whether or not the input MASK_CT is 0. In a case where the MASK_CT is other than 0, the comparator 130 outputs a signal. On the other hand, in a case where the MASK_CT is 0, the comparator 130 does not output a signal. For example, the comparator 130 stops outputting of a signal when the mask counter is initialized, and when count-up is started in response to issuance of an ACT command after that, the comparator 130 outputs a signal until the next initialization is performed.

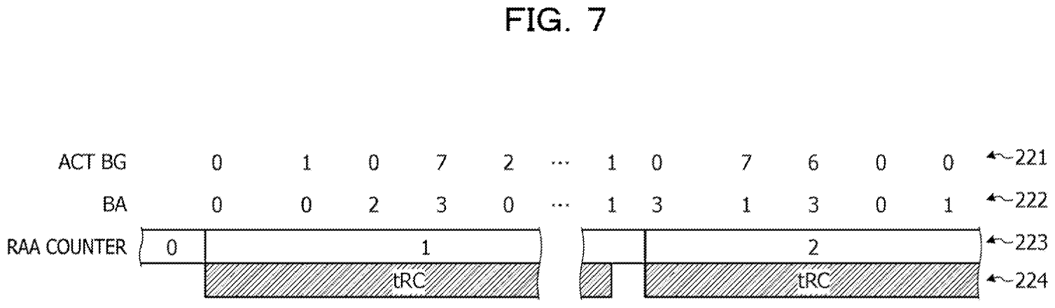

FIG. 7 is a time chart illustrating transition of the RAA counter according to the second embodiment. Next, the transition of the RAA counter according to the present embodiment will be described with reference to FIG. 7. Here, since all banks in the same rank are objects to be managed, banks of bank groups 1 to 7 are objects to be managed by one refresh management control circuit 110.

Lines 221 and 222 in FIG. 7 indicate a bank group and a bank address specified by an ACT command. Furthermore, a line 223 indicates a value of the RAA counter. Moreover, a line 224 represents a state of masking.

In a state where the RAA counter is 0, an ACT command is issued with a bank group of 0 and a bank address of 0 as destinations, whereby the RAA counter becomes 1. At this timing, masking until a mask counter reaches tRC is started as indicated in the line 224. Next, an ACT command is issued with a bank group of 1 and a bank address of 0 as destinations. However, in this case, since masking is performed and a signal is not input to the AND circuit 116, and as a result, a signal is not input to the RAA counter FF 113, the RAA counter does not increase and maintains the value of 1. Thereafter, an ACT command with a bank group of 0 and a bank address of 2 as destinations and an ACT command with a bank group of 7 and a bank address of 3 as destinations are sequentially issued. However, the RAA counter maintains the value of 1. Then, at timing when an ACT command is issued with a bank group of 1 and a bank address of 1 as destinations, the mask counter reaches the tRC and masking is cancelled. Then, when the next ACT command is issued with a bank group of 0 and a bank address of 3 as destinations, the RAA counter is increased by one to become 2. At this timing, masking until the mask counter reaches the tRC is started again as indicated in the line 224. In this way, even when an ACT command is issued to a bank to be managed, the RAA counter does not increase during a period in which masking is performed, but increases at timing when masking is cancelled.

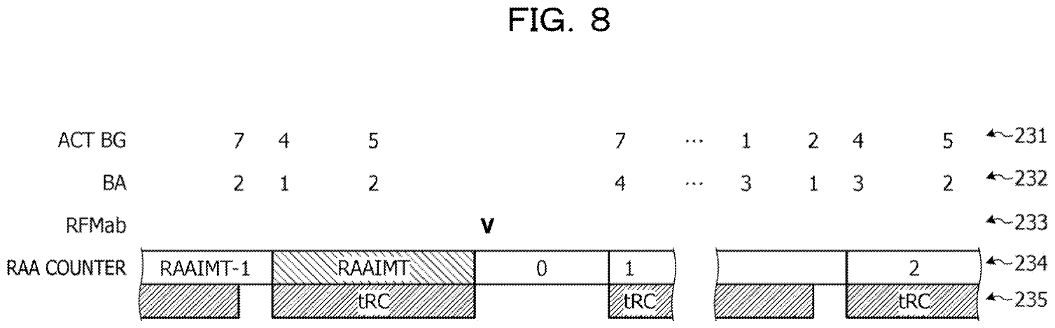

FIG. 8 is a time chart illustrating transition of the RAA counter in a case where an RFM issuance request according to the second embodiment is output. Next, with reference to FIG. 8, the transition of the RAA counter in a case where an RFM issuance request is made to the pipeline 101 will be described. Here, since all banks in the same rank are objects to be managed, banks of bank groups 1 to 7 are objects to be managed by one refresh management control circuit 110.

Lines 231 and 232 in FIG. 8 represent a bank group and a bank address, which are destinations of an issued ACT command. Furthermore, a line 233 represents RFMab issuance timing. Furthermore, a line 234 represents a value of the RAA counter. Furthermore, a line 235 represents a state of masking.

In FIG. 8, in a state where the value of the RAA counter is “RAAIMT-1”, an ACT command is issued with a bank group of 7 and a bank address of 2 as destinations, whereby the RAA counter is increased by one to reach “RAAIMT”. At this point, since the RAA counter is equal to or greater than the RAAIMT, an RFM issuance request is output to the pipeline 101. Then, the pipeline 101 outputs an RFMab to a memory 2. In FIG. 8, a check symbol “V” represents the output of the RFMab. Then, an REF_GO signal is input to the refresh management control circuit 110, the RAAIMT is subtracted from the RAA counter, and the RAA counter becomes 0.

Thereafter, an ACT command is issued with a bank group of 7 and a bank address of 4 as destinations, whereby the RAA counter becomes 1. At this timing, masking until a mask counter reaches tRC is started as indicated in the line 235. Then, an ACT_GO signal is sequentially input to the refresh management control circuit 110, and when the mask counter reaches the tRC, masking is cancelled. Thereafter, an ACT command is issued with a bank group of 4 and a bank address of 3 as destinations, whereby the RAA counter becomes 2. At this timing, masking until the mask counter reaches the tRC is started again as indicated in the line 235.

Thereafter, when ACT commands are issued to the banks of the bank groups 1 to 7, the RAA counter of the refresh management control circuit 110 is incremented by one each time masking of the tRC is cancelled. In this way, in the refresh management control circuit 110 according to the present embodiment, it is repeated that, when an ACT command is issued to each bank to be managed, masking is performed for a certain period and an input of the ACT command is not counted, and the ACT command is increased by one after the masking is cancelled. Then, when the total number becomes equal to or greater than the RAAIMT, an RFMab is sent and the RAAIMT is subtracted from the RAA counter.

For example, in the refresh management control circuit 110 according to the present embodiment, after an ACT command is input to any one of the banks to be managed and the RAA counter is incremented, the refresh management control circuit 110 stands by without performing counting in a tRC period. By suppressing counting by the RAA counter in this way, it is possible to avoid excessive count-up of the RAA counter. Furthermore, since the tRC is a period in which an ACT command is issued to one bank and then an ACT command is not issued to the same bank, two or more ACT commands are not issued to another bank within this period. Thus, after an ACT command is issued to a certain bank and the RAA counter is incremented, an ACT command is not issued to the same bank during the tRC period, and the number of ACT commands issued to another bank is at most 1. Therefore, in a case where the RAA counter according to the present embodiment reaches the RAAIMT, there is no bank that has received more ACT commands than the RAAIMT, and it may be said that appropriate refresh is performed.

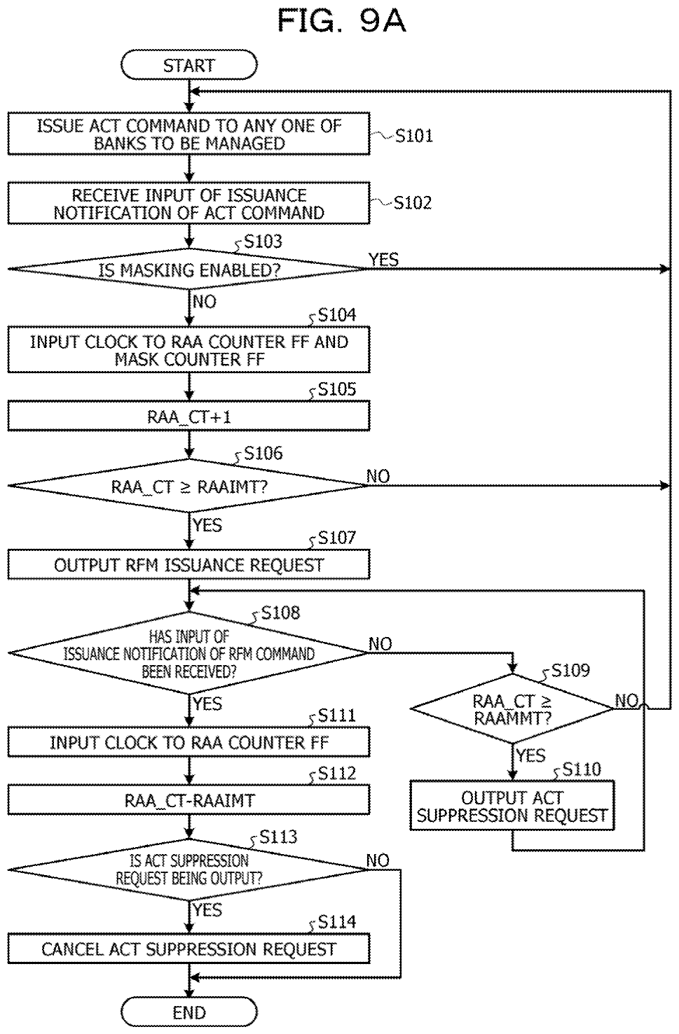

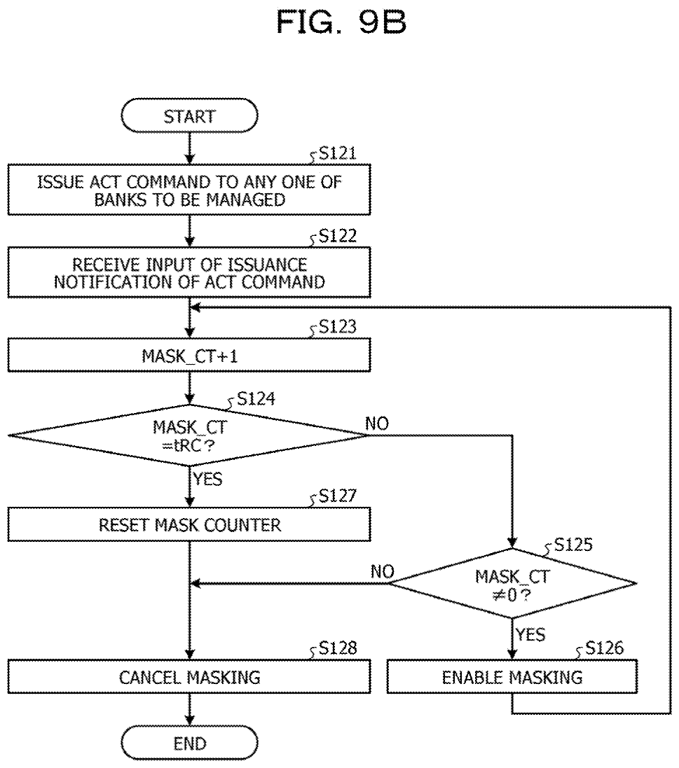

FIG. 9A is a first flowchart of refresh management according to the second embodiment. FIG. 9B is a second flowchart of the refresh management according to the second embodiment. Next, a flow of the refresh management according to the present embodiment will be described with reference to FIGS. 9A and 9B. Here, a flow of refresh by issuance of an RFM command up to RAA counter subtraction will be described. Since the RAA counter and the mask counter operate in parallel, a flow of processing for each counter will be described separately. First, the flow of processing using the RAA counter will be described with reference to FIG. 9A.

A memory access request is input to the pipeline 101. Then, an ACT command is issued from the pipeline 101 to any one of banks to be managed of the memory 2 (operation S101).

Thereafter, the refresh management control circuit 110 receives an input of an issuance notification of the ACT command from the pipeline 101 (operation S102).

The AND circuit 122 determines whether or not masking is enabled by an inverted signal from the comparator 130 (operation S103). In a case where masking is enabled (operation S103: Yes), the refresh management processing returns to the operation S101.

On the other hand, in a case where masking is disabled (operation S103: No), a clock is input to the RAA counter FF 113 and the mask counter FF 125 (operation S104).

Furthermore, the OR circuit 114 outputs an input ACT_GO signal to the AND circuit 116 regardless of which bank to be managed the ACT command is addressed to. When receiving the input of the ACT_GO signal, the AND circuit 116 outputs a value obtained by adding 1 to an RAA_CT to the RAA counter FF 113 via the OR circuit 117 (operation S105).

The RAA counter FF 113 uses the clock input from the clock output circuit 112 to output the value obtained by adding 1 to the previous RAA_CT input from the AND circuit 116 as an RAA_CT. The comparator 118 determines whether the RAA_CT output from the RAA counter FF 113 is equal to or greater than the RAAIMT (operation S106). In a case where the RAA_CT is less than the RAAIMT (operation S106: No), the refresh management processing proceeds to the operation S101.

On the other hand, in a case where the RAA_CT is equal to or greater than the RAAIMT (operation S106: Yes), the comparator 118 outputs an RFM issuance request to the internal command generation unit 103 (operation S107).

The internal command generation unit 103 that has accepted the RFM issuance request inputs an RFM command to the pipeline 101. Thereafter, the refresh management control circuit 110 determines whether or not an input of an issuance notification of the RFM command has been received (operation S108). Here, it is determined whether or not the input of the issuance notification of the RFM command has been received depending on whether or not an REF_GO signal notifying issuance of the RFM command has been input to the OR circuit 111 and the AND circuit 115.

In a case where the input of the issuance notification of the RFM command has not been received (operation S108: No), the comparator 119 determines whether or not the RAA_CT is equal to or greater than the RAAMMT (operation S109). In a case where the RAA_CT is less than the RAAMMT (operation S109: No), the refresh management processing returns to the operation S101.

On the other hand, in a case where the RAA_CT is equal to or greater than the RAAMMT (operation S109: Yes), the comparator 119 outputs an ACT suppression request to the pipeline 101 (operation S110). Thereafter, the refresh management processing returns to the operation S108.

On the other hand, in a case where the input of the issuance notification of the RFM command has been received (operation S108: Yes), which is, in a case where the REF_GO signal is input to the OR circuit 111 and the AND circuit 115, the following processing is performed. When receiving the input of the REF_GO signal, the OR circuit 114 inputs an enable signal to the clock output circuit 112. When receiving the input of the enable signal, the clock output circuit 112 inputs a clock to the RAA counter FF 113 (operation S111).

When receiving the input of the REF_GO signal, the AND circuit 115 outputs a value obtained by subtracting the RAAIMT from the RAA_CT to the RAA counter FF 113 via the OR circuit 117 (operation S112).

Thereafter, when receiving the input of the RAA_CT having a value less than the RAAIMT, the comparator 119 determines whether or not an ACT suppression request is being output (operation S113). In a case where the ACT suppression request is not being output (operation S113: No), the comparator 119 maintains the output state in which the ACT suppression request is not being output. On the other hand, in a case where the ACT suppression request is being output (operation S113: Yes), the comparator 119 cancels the ACT suppression request (operation S114).

Thus, the processing in the flow of FIG. 9A ends, but in reality, the processing returns to the operation S101 after that, and similar refresh management processing is repeated. Furthermore, next, the flow of processing using the mask counter will be described with reference to FIG. 9B.

A memory access request is input to the pipeline 101. Then, an ACT command is issued from the pipeline 101 to any one of banks to be managed of the memory 2 (operation S121).

Thereafter, the refresh management control circuit 110 receives an input of an issuance notification of the ACT command from the pipeline 101 (operation S122).

When receiving an input of an ACT_GO signal, the OR circuit 123 outputs a signal to the clock output circuit 124. The clock output circuit 124 outputs a clock to the mask counter FF 125. At this time, since the OR circuit 126 receives neither an input of an REF_GO signal nor an input of a signal from the comparator 129, the OR circuit 126 does not output a signal. Thus, the AND circuit 127 receives an input of an inverted signal from the OR circuit 126. Moreover, the AND circuit 127 receives an input of a signal of 1 to a value of the mask counter that has been reset to 0 output from the mask counter FF 125. Then, the AND circuit 127 outputs, to the mask counter FF 125, a value obtained by adding 1 to the value of the mask counter in the reset state, which is the previous output from the mask counter FF 125. The mask counter FF 125 uses the input from the AND circuit 127 as the next MASK_CT. For example, the mask counter FF 125 uses a MASK_CT+1 as the next MASK_CT (operation S123). Then, the mask counter FF 125 outputs the MASK_CT.

The comparator 129 determines whether or not the MASK_CT has reached tRC (operation S124). In a case where the MASK_CT has not reached the tRC (operation S124: No), the comparator 129 does not output a signal. Then, the comparator 130 determines whether or not the MASK_CT is other than 0 (operation S125). In a case where the MASK_CT is 0 (operation S125: No), the refresh management processing proceeds to operation S128.

On the other hand, in a case where the MASK_CT is other than 0 (operation S125: Yes), the comparator 130 outputs a signal. In this case, the AND circuit 122 does not receive an input of an inverted signal from the comparator 130. For example, the comparator 130 enables masking (operation S126). Thereafter, the refresh management processing returns to the operation S123.

On the other hand, in a case where the MASK_CT has reached the tRC (operation S124: Yes), the comparator 129 outputs a signal to the OR circuit 126. The OR circuit 126 outputs the signal to the AND circuit 127. With this configuration, an inverted signal of the OR circuit 126 is not input to the AND circuit 127, and the AND circuit 127 stops outputting a signal. When the input of the signal from the AND circuit 127 is interrupted, the mask counter FF 125 outputs 0 as the MASK_CT. For example, the mask counter FF 125 resets the mask counter (operation S127). When the MASK_CT is set to 0, the refresh management processing proceeds to the operation S128.

Since the MASK_CT is 0, the comparator 130 stops outputting a signal. In this case, the AND circuit 122 receives an input of an inverted signal from the comparator 130. For example, the comparator 130 cancels masking (operation S128).

Thus, the processing in the flow of FIG. 9B ends, but in reality, the processing returns to the operation S121 after that, and similar refresh management processing is repeated.

By controlling the refresh management with the above configuration, the number of counts of the RAA counter may be reduced. For example, the maximum value of the tRC currently used is 159 cycles of DDR5-6400C, and a bit width of the mask counter may be 8 bits. In that case, the number of flip-flops used is 8+9=17 bits per rank, and when there are 16 ranks, the number of flip-flops used is 17×16=272 bits. Therefore, a physical amount may be suppressed to about 1/17 of the case where the RAA counter is provided for each bank.

As described above, the memory access controller according to the present embodiment integrates the RAA counters into one with a plurality of banks to be managed, and controls issuance of an additional refresh command while avoiding excessive counting of the RAA counter. For example, in a case where the RAA counter is incremented by transmission of an ACT command to a certain bank, thereafter, the increment of the RAA counter is suppressed until the transmission of the ACT command to that bank is permitted. With this configuration, it is possible to reduce a physical amount of the circuit that controls the refresh management while further suppressing excessive issuance of an additional refresh command. As a result, power consumption of the memory access controller may also be reduced.

[Information Processing Device]

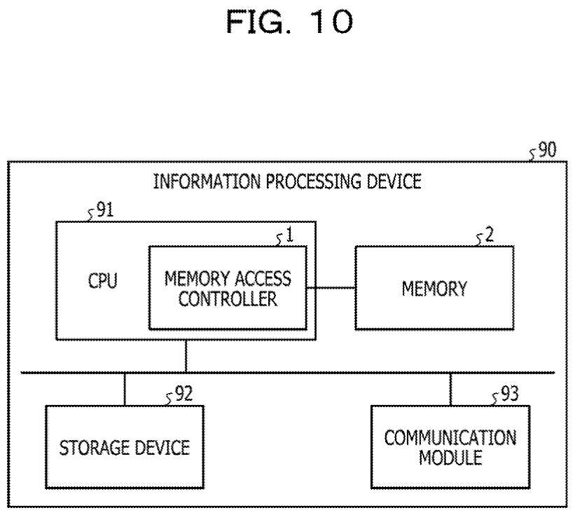

FIG. 10 is a hardware configuration diagram of an information processing device. The memory access controller 1 described in each of the above embodiments may be mounted on an information processing device 90 as illustrated in FIG. 10.

The information processing device 90 includes a CPU 91 having the memory access controller 1, the memory 2, a storage device 92, and a communication module 93. The CPU 91 controls the memory 2 via the memory access controller 1. Furthermore, the CPU 91 is connected to the storage device 92 and the communication module 93 by a bus. The CPU 91 reads a program or the like stored in the storage device 92, develops the program or the like into the memory 2, and executes the program or the like to operate various applications. The CPU 91 may operate various applications while reading and writing data to and from the memory 2 via the memory access controller 1.

Furthermore, in the above description, the memory access controller 1 is implemented by using an electronic circuit, but the embodiments are not limited to this, and for example, a program may also be operated by a processor to implement each processing of the memory access controller 1.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A memory management apparatus comprising:
a memory; and
a processor coupled to the memory and configured to:
receive a notification of issuance of an activation instruction to each bank included in a predetermined group among a plurality of banks included in the memory;
count a number of the received notifications;
cause the memory to be refreshed in a case where a count value of the counting reaches a refresh threshold; and
reduce the count value by a value of the refresh threshold in a case where the memory is refreshed.

2. The memory management apparatus according to claim 1, wherein the processor is further configured to stop the issuance of the activation instruction to the bank included in the predetermined group in a case where the count value reaches an issuance stop upper limit value.

3. The memory management apparatus according to claim 1, wherein the processor is further configured to perform pipeline processing on an access request to the memory, and output an activation instruction to the bank specified by the access request.

4. The memory management apparatus according to claim 3, wherein the processor is configured to refresh the memory in a case where the refresh of the memory is instructed.

5. The memory management apparatus according to claim 1, wherein the processor is further configured to generate an internal command and cause the memory to be refreshed in a case where a refresh instruction is received or in a case where a predetermined time has elapsed.

6. The memory management apparatus according to claim 1, wherein the processor is further configured to stop the count for a predetermined period after the count value is increased.

7. A memory management method comprising:
receiving a notification of issuance of an activation instruction to each bank included in a predetermined group among a plurality of banks included in a memory;
counting a number of the received notifications;
causing the memory to be refreshed in a case where a count value of the counting reaches a refresh threshold; and
reducing the count value by a value of the refresh threshold in a case where the memory is refreshed.

8. A non-transitory computer-readable recording medium storing a memory management program that causes a computer to execute a process, the process comprising:
receiving a notification of issuance of an activation instruction to each bank included in a predetermined group among a plurality of banks included in a memory;
counting a number of the received notifications;
causing the memory to be refreshed in a case where a count value of the counting reaches a refresh threshold; and
reducing the count value by a value of the refresh threshold in a case where the memory is refreshed.
